(19) United States
(12) Patent Application Publication
(10) Pub. No.: US 2026/0111754 A1
(43) Pub. Date: Apr. 23, 2026

(54) METHOD AND APPARATUS TO OVERCOME SIGNAL FLUCTUATIONS IN EDGE COMPUTING USING A HYBRID STRATEGY FOR LATENCY-SENSITIVE APPLICATIONS

(71) Applicant: Cisco Technology, Inc., San Jose, CA (US)

(72) Inventors: Karthik Babu Harichandra Babu, San Ramon, CA (US); Sridhar Santhanam, Dublin, CA (US)

(21) Appl. No.: 18/921,991

(22) Filed: Oct. 21, 2024

(51) Int. Cl. G06N 3/098; H03M 7/30

(52) U.S. Cl. CPC G06N 3/098; H03M 7/30

(57) ABSTRACT

This disclosure describes techniques for overcoming signal fluctuations to enhance the robustness of transmission of data blocks within a Multi-access Edge Computing (MEC) environment. A user equipment in a MEC environment, that includes a transceiver; and a controller to receive, from an edge computing device, data that includes metric of data related to a network transmission received by the transceiver; input, to a neural network model data of the at least one type of metric of data to determine an amount of signal fluctuation in the network transmission; determine, based on an output from the neural network model, a compression ratio for compressing data of a block of data used in a transceiver-based transmission to an edge computing device; and iteratively adjust the compression ratio to compress the block of data in response to changes in the amount of signal fluctuation based on output from the neural network model.

### TECHNICAL FIELD

The present disclosure relates generally to networking and, more particularly, to techniques for handling signal fluctuations using federated learning for mobile edge computing within a network.

### BACKGROUND

Mobile Edge Computing (MEC) promises faster response times and reduced latency by processing data closer to end users. However, fluctuating network conditions, particularly weak signal strength, and limited bandwidth, can significantly hamper performance. Traditional static compression techniques fail to adapt to these changing environments, leading to increased latency and degraded accuracy. In some examples, edge computing and edge devices are implemented to reduce processing demands centrally (.e., off-loading the demands of more centralized processors). They may also replace local computing demands when acquiring low-latency quality of service in a 5G network. Edge computing can replace local computing to acquire low-latency quality of service in 5th-generation networks.

Training a neural network can be time fatiguing and require substantial amounts of use data to attain a necessary level of accuracy. In some examples, federated learning is improving or making more fruitful a customary process that may be used to train a local neural network by the user equipment that limits the processing requirements necessary for the local user equipment. In some examples, federated learning may enable multiple user equipment (i.e., multiple entities) with different data generated or received to learn from a singularly connected neural network while still being able to maintain privacy and not sharing data between each other. Moreover, federated learning has proved advantageous as it may enable a number of users (i.e., user equipment) to individually train concurrently in a neural network, with the training performed locally by the user equipment.

In some examples, interruptions in the signal connectivity to a receiver or transceiver of a local user may occur when signal fluctuations occur. One such interruption is a path loss caused by a signal weakness fluctuation resulting in the signal fading. This may happen due to attenuation of signal power between the receiving and transmitting stations caused by environmental factors or simply the signal power available or dues signally properties such as the signal's physical propagation mechanisms such as reflection, refraction, diffraction, and scattering.

In some examples, machine learning is a technique to improve system performance based on a flexible model architecture and a good amount of appropriate data. One type of machine learning uses an Artificial Neural Network (ANN), which is an adaptive system that makes modifications to its structure and response characteristics during a training process. ANN may be used for path loss predictions to overcome the shortcomings of empirical and deterministic models.

Accordingly, a more robust, accurate, and dynamic solution for monitoring signal fluctuations is needed to prevent signal loss and maintain the robust transmissions of data blocks in response to changes in received signal strength.

### BRIEF DESCRIPTION OF THE DRAWINGS

The detailed description is set forth below with reference to the accompanying figures. In the figures, the left-most digit(s) of a reference number identifies the figure in which the reference number first appears. The use of the same reference numbers in different figures indicates similar or identical items. The systems depicted in the accompanying figures are not to scale and components within the figures may be depicted not to scale with each other.

FIG. 1 illustrates a system architecture diagram of the Mobile Edge Computing (MEC) Environment in which the dynamic changing of compression ratios for compressing data blocks in response to received signal fluctuations is supported according to some embodiments.

FIG. 2 illustrates a diagram of an example network for monitoring signal fluctuations received from transmitted signals from one or more base stations to user equipment, adjusting compression ratios of blocks data being transmitted from local devices, and sending updates of changes of a local neural network model to a global model stored at one or more MEC servers where the local models are trained using a federated learning process according to some embodiments.

FIG. 3 illustrates a diagram of activities between the base station, the user equipment, and the server according to some embodiments.

FIG. 4 is an exemplary federated learning process of a collaborative, decentralized framework for sharing neural network model updates between the local user equipment and a global model remotely hosted according to some embodiments.

FIGS. 5A and 5B illustrate flow diagrams of an example method for a system for Mobile edge computing that handles signal fluctuations and uses federated learning for distributed learning according to some embodiments.

FIG. 6 is a computer architecture diagram showing an illustrative computer hardware architecture for implementing a server device that can be utilized to implement aspects of the various technologies presented herein.

### DESCRIPTION OF EXAMPLE EMBODIMENTS

### Overview

The present disclosure generally relates to techniques for dynamically monitoring fluctuations in signals being received from an edge device in a Multi-Access Edge Computing (MEC) environment using a neural network that is trained independently by a federated learning process and adjusting compression ratios of blocks of data being transmitted from the local device in response to outputs of the neural network.

Some examples provide user equipment for processing data in a multi-access edge computing (MEC) environment. The method includes a transceiver and a controller coupled to the transceiver configured to receive, from an edge computing device, data that comprises at least one type of metric of data related to a network transmission received by the transceiver within the MEC environment: input, to a neural network model communicatively coupled to the controller, data of the at least one type of metric of data to determine an amount of signal fluctuation in the network transmission; determine, based on an output from the neural network model, a compression ratio for compressing data of a block of data used in a transceiver-based transmission to an edge computing device within the MEC environment; and iteratively adjust the compression ratio for compressing the block of data in response to changes in the amount of signal fluctuation based on output from the neural network model to enhance the transceiver-based transmission to the edge computing device within the MEC environment.

In some examples, the neural network model is trained using a federated learning process based on at least one type of metric of data associated with a signal fluctuation within the MEC environment.

In some examples, the controller is further configured to select an optimal compression for each block of data based at least on one type of metric of data of a plurality of metrics of data before transmitting the block of data to the edge computing device within the MEC environment.

In some examples, the controller is further configured to apply on-device processing for latency-sensitive data.

In some examples, the controller is further configured to execute the neural network model to process non-latency-sensitive or less critical data.

In some examples, the controller is further configured to apply a plurality of compression rates comprising at least one of a high, medium, or low compression ratio based on the output from the neural network model.

In some examples, the user equipment includes a gating mechanism in operable communication with the controller wherein the gating mechanism is configured as an adaptive gating mechanism to adjust the compression ratio of the block of data in the transceiver-based transmission.

In some examples, the adaptive gating mechanism is further configured to respond to a determination by the controller of whether a data check-in by the edge computing device has been omitted and to use a previously received update from the controller to compensate for an omitted data check-in to adjust the compression ratio of the block of data in the transceiver-based transmission.

In some examples, the network transmission comprises an uplink transmission received from the transceiver and a downlink transmission sent to the transceiver from the edge computing device within the MEC environment.

In some examples, the controller is configured to send data generated by an update from the output of the neural network model to a global neural network model hosted within the MEC environment.

Some examples provide a method for processing data in the Multi-access Edge Computing environment to respond to frequency changes. The method includes receiving, by a local device in a MEC environment, a transmission of a radio frequency signal from an edge device within the MEC environment; determining, by the local device, at least one metric of data related to the transmission of the radio frequency signal from the edge device within the MEC environment; inputting, by the local device in operable communication with a neural network model, the at least one metric of data to the neural network model wherein the neural network model is trained using a federated learning process based on metric data associated with at least one radio frequency signal transmission; receiving, by the local device, an output from the neural network model that provides an evaluation of signal fluctuation in the transmission of the radio frequency signal to the local device based on inputted metric data; and iteratively changing, by the local device based on the output from the neural network model, a compression ratio to apply for compressing a data block in the transmission of a radio signal from the local device to the edge device in a MEC environment wherein the data block is being compressed in accordance with signal fluctuation from the transmission from the edge device.

In some examples, the method includes processing on-device by the local device for latency-sensitive data or critical data in transmissions between the local device and edge device.

In some examples, the method includes using the local device's neural network model for processing non-latency sensitive data or less critical data in transmission between the local device and the edge device.

In some examples, the method includes the local device selecting an optimal compression block for each data block before transmission to the edge device.

In some examples, the method includes training a neural network model hosted at a local device via the federated learning process using an independent input of metric data from at least one local device.

In some examples, the method includes enabling, by the local device, an adaptive gating mechanism for adjusting the compression ratio of the data block in the transmission of data between the local device and the edge device.

In some examples, the compression ratio comprises at least one of a high compression ratio, a medium compression ratio, or a low compression ratio.

In some examples, the method includes sending, by the local device, one or more updates of changes to the neural network model to a global network model remotely hosted by a server in the MEC environment.

Some examples provide a system in a multi-access edge computing (MEC) environment for processing data. The system includes one or more processors; and non-transitory computer-readable media storing instructions that, when executed by the one or more processors, cause the system to perform operations includes: receiving, by a local device in a Multi-access Edge Computing (MEC) environment, a transmission of a radio frequency signal from an edge device within the MEC environment; determining, by the local device, at least one type of metric of data related to the transmission of the radio frequency signal from the edge device within the MEC environment; inputting, by the local device in operable communication with a neural network model, the at least one type of metric of data to the neural network model wherein the neural network model is trained using a federated training process based on at least one kind of metric of data associated with at least one radio frequency signal transmission; receiving, by the local device, an output from the neural network model that provides an evaluation of signal fluctuation in the transmission of the radio frequency signal to the local device based on inputted metric data; and iteratively changing, by the local device based on the output from the neural network model, a compression ratio to apply for compressing a data block in the transmission of a radio signal from the local device to the edge device in an MEC environment wherein the data block is being compressed in accordance with signal fluctuation from the transmission from the edge device.

In some examples, the system includes a gating mechanism in operable communication with the local device. The gating mechanism is configured as an adaptive gating mechanism to adjust the compression ratio of block data in a transmission between the local device and the edge device.

Additionally, the techniques described herein may be performed by a system and device with non-transitory computer-readable media storing computer-executable instructions that perform the method described above when executed by one or more processors.

### Example Embodiments

The present invention is a method for real-time data processing in edge computing environments under fluctuating signal strength conditions. It combines on-device processing for latency-sensitive data with a dynamically adaptive Federated Neural Network Compression (FDNNC) model for less critical data, ensuring uninterrupted responsiveness and efficient off-loading even during signal fluctuations.

This disclosure describes techniques and mechanisms for mobile edge computing, handling signal fluctuations, and using federated learning for distributed learning. In some examples, the system uses a federated learning model and an adaptive gating mechanism to optimize data compression and transmission. In some examples, the system and method described apply on-device processing for latency-sensitive data while using a neural network model on a device to handle and configure the data transmission and processing of less urgent data. In some examples, the system and methods provided continuously monitor network metrics and choose an optimal compression ratio for a block of data or a data packet before transmission locally to an edge device or server within the MEC environment.

In some examples, an aggregator is configured to selectively aggregate and send data to a global model. The global model is a centralized storage or repository for collecting and analyzing information from one or more distributed models. Based on its predictive power, the aggregated global model improves compression efficiency and data fidelity.

In some examples, the on-device processing configured at the user equipment, such as a local user device, may use separate lightweight models for instant decisions, while the FDNNC model uses federated learning for other non-critical data processing. The FDNNC model may be considered the basis for the adaptive gating mechanism to categorize compressions into high, medium, and low ratios needed for optimal data block transfer.

In some examples, metrics such as signal strength, geographic locations, and bandwidth determine signal fluctuation and necessary check-ins may be used to formulate predictions of signal strength and signal fluctuations.

In some examples, the present invention is directed to a smart methodology for monitoring one or more parameters in a radio transmission to determine or predict the amount of signal fluctuations using a machine learning schema that is trained in part using a federated learning process. In some examples, in response to one or more levels of signal fluctuations learned in a received transmitted signal, various configurations of compression ratios are applied to blocks of data before being transmitted by a local transceiver or transmitter to improve signal integrity and reception by edge devices.

In some examples, one or more radio transmission parameters may be used as input to a neural network to determine or predict real-time signal fluctuations that occur or may occur in a signal being sent by a base station to a user device. In some examples, processing the signal data and evaluating the signal is performed locally by a neural network rather than off-loading the processing to a centralized processor.

In some examples, the adaptive parameters are compression levels of data blocks to be transmitted in response to signal fluctuations determined. While the present disclosure describes adapting compression levels for data block transmission responsive to signal fluctuations, it is contemplated that the disclosure is not so limiting. Other radio transmission parameters can also be adaptive to signal fluctuations, e.g., the constellation size, coding rate, transmit power, precoding codeword, time and frequency resource block, transmit antennas, and relays, to instantaneous channel conditions. The result is that an adaptive wireless system can potentially aid in achieving a more robust communication performance.

In a 5G network, a service provider may implement Network Slicing to dedicate portions of their network to meet their customers'specific needs. For example, in 5G networks, “Network Slicing” is where a user requests a particular service “intent” (or outcome) required to be provided by the network (i.e., Ultra-Reliable Low Latency (URLLC) or enhanced Mobile Broadband (eMBB) for high bandwidth services) with the expectation that the service provider can satisfy that intent.

In some examples, the present invention may employ controller-based machine learning techniques to control adaptive gating mechanisms for use in federated learning processes to train local neural models. The machine learning techniques may include, but are not limited to, supervised learning algorithms (e.g., artificial neural networks, Bayesian statistics, support vector machines, decision trees, classifiers, k-nearest neighbor, etc.), unsupervised learning algorithms (e.g., artificial neural networks, association rule learning, hierarchical clustering, cluster analysis, etc.), semi-supervised learning algorithms, deep learning algorithms, etc.), statistical models, etc. As used herein, the terms “machine learning,” “machine-trained,” and their equivalents may refer to a computing model that can be optimized to accurately recreate specific outputs based on certain inputs. In some examples, the machine learning models include deep learning models, such as convolutional neural networks (CNN), deep learning neural networks (DNN), and artificial intelligence models.

In some examples, the term “neural network” and its equivalents may refer to a model with multiple hidden layers, wherein the model receives an input (e.g., a vector) and transforms the input by performing operations via the hidden layers. An individual hidden layer may include multiple “neurons,” each of which may be disconnected from other neurons in the layer. An individual neuron within a particular layer may be connected to multiple (e.g., all) neurons in the previous layer. A neural network may include at least one fully connected layer that receives a feature map output by the hidden layers and transforms the feature map into the neural network's output. In some examples, the neural network comprises a graph where each node of the graph represents a layer within the neural network. Each node may be connected as a chain (e.g., a concatenation of layers). In some examples, input may be received by a node within the graph; the input is computed by the node and passed to one or more additional nodes in the chain.

In some examples, the compression ratio is the ratio of the compressed data's size to the original data's size. It measures how much the algorithm can reduce the data size without losing information. The compression ratio can vary depending on the type and compressibility of the data, as well as the settings and parameters of the algorithm. In some examples, the compression ratio may be calculated by dividing the compressed data size by the original data size and multiplying it by 100%.

While the examples described focus on an embodiment related to a 5G network, it should be noted that the techniques described herein may apply to any network and service that provides transport services and supports an application across transport networks.

Certain implementations and embodiments of the disclosure will now be described more fully below with reference to the accompanying figures, in which various aspects are shown. However, the various aspects may be implemented in many different forms and should not be construed as limited to the implementations set forth herein. The disclosure encompasses variations of the embodiments as described herein like numbers refer to like elements throughout.

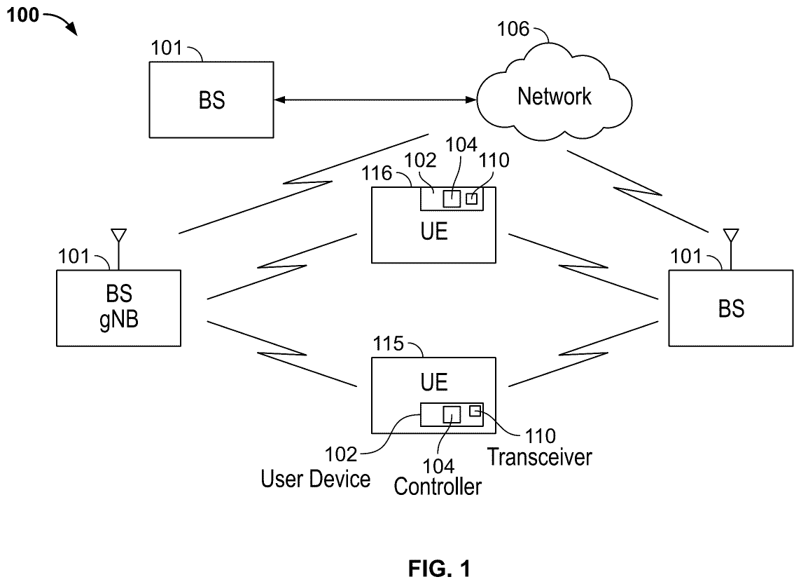

FIG. 1 illustrates a system architecture diagram of MEC Environment 100 in which the dynamic changing of compression ratios for compressing data blocks in response to received signal fluctuations is supported according to some embodiments. The user device(s) 102 may include one or more device(s) for various user equipment 115, 116. It may comprise any computing device, such as a mobile device, laptop, computer, tablet, Wi-Fi-enabled device, cellular-enabled device, and Bluetooth-enabled device. In some examples, the user device 102 may correspond to the device of an administrator (not shown). The user device 102 may include one or more application(s) (not shown).

In some examples, the user device 102 may communicate with one or more controllers 104 via network(s) 106 and with a number of base stations 101. Network(s) 106 may include any combination of Personal Area Networks (PANs), Local Area Networks (LANs), Campus Area Networks (CANs), Metropolitan Area Networks (MANs), extranets, intranets, the Internet, Wide Area Networks (WANs)—both centralized and/or distributed - and/or any combination, permutation, and/or aggregation thereof. In some examples, the network(s) 106 may correspond to a private enterprise network, a cellular network (e.g., such as a 5G network), or any other type of network. The user device(s) 102 may communicate using any type of protocol over the network(s) 106, such as the transmission control protocol/Internet protocol (TCP/IP) that is used to govern connections to and over the Internet.

In some examples, controller 104 is configured to receive a slice provisioning request from the user device 102. In some examples, the controller 104 may comprise a computing device, processor(s), memory, etc. For instance, the controller 104 may correspond to a 5G network. In some examples, the controller 104 instructs a transceiver 110 to adjust the compression of blocks of data to be transmitted in a transmission to a base station 101.

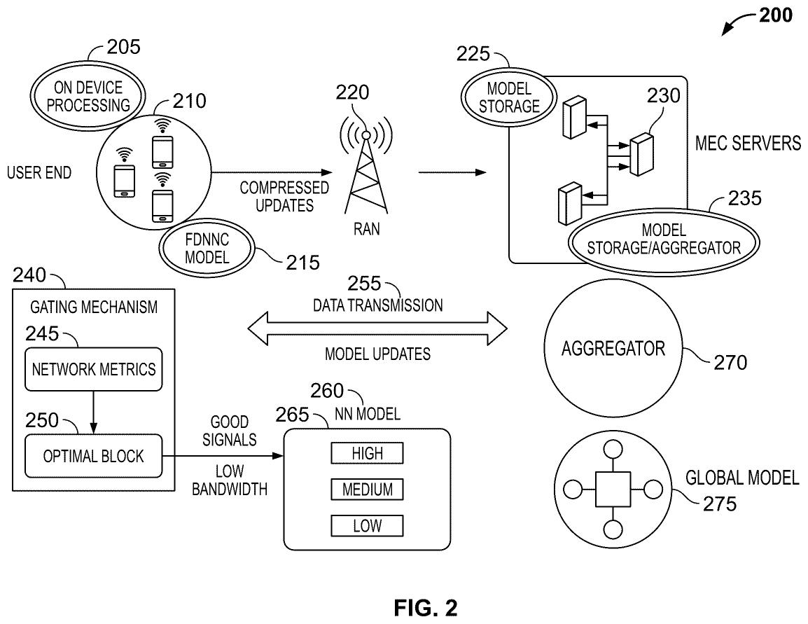

FIG. 2 illustrates a diagram of an example network for monitoring signal fluctuations received from transmitted signals from one or more base stations to user equipment, adjusting compression ratios of blocks data being transmitted from local devices, and sending updates of changes of a local neural network model to a global model stored at one or more MEC servers where the local models are trained using a federated learning process according to some embodiments.

In FIG. 2, in network 200, there is shown an on-device processing 205 performed by user equipment 210 that applies a federated learning process model 215 to send compressed updates of compression ratios in response to determinations of signal fluctuations received from transmitted signals from the base station 220. In some examples, the Federated Neural Network Compression (FDNNC) model can be a dynamic compression model that employs one or more neural network (NN) blocks with varying compression ratios. In some examples, each user equipment (UE) 210 triggers updates (i.e., compressed updates) to the base station 220. In some examples, Federated Learning (FL) is implemented as a fallback process to collect metric parameters of signal strengths from the signals transmitted from base station 220.

In some examples, the FL periodically snapshots a vector of the necessary measurements and regularly sends these snapshots to a measurement endpoint. UEs with strong connections collaboratively refine the FDNNC model by securely sharing updates containing only the optimized block parameters. The measurement endpoint is used to a) cumulate the metrics necessary for the signal fluctuation, b) determine when the necessary check-ins have not occurred and fall back to updates, and c) respond to changes in the s0-sK (UE->MED) path relevant to steps (a) and (b). The aggregated global model 275 via the aggregator 270 further improves compression efficiency and data fidelity across the network based on the model's predictive power. This may assist in obtaining the needed metrics in advance of a time and when needed.

In some examples, on-device processing for instant decisions includes the latency-sensitive data being handled instantaneously on the edge device itself. In some examples, the on-device processing may be considered a localized function that enables instant or nearly instantaneous decision-making without requiring input from a remote resource or third-party authority to formulate a decision (i.e., without needing to consult a distant authority).

In some examples, the FDNNC Model and the Adaptive Gating Mechanism 240 contain the network metrics 245, and the optimal block 250 configuration means to determine high, medium, and low compression ratios (module 265). However, for less urgent data, a more flexible approach is required or maybe needed. The FDNNC model, residing on the device, may provide the capability to process less urgent data. In some examples, the FDNNC model boasts multiple neural network compression blocks, each offering different levels of compression (high, medium, low) 265. An adaptive gating mechanism 240 (i.e., a smart gating mechanism) continuously monitors network metrics 245, like signal strength and bandwidth. The smart gating mechanism 240 may operate like a manager to enable the choosing of an optimal compression block 250 for each data packet before transmission, ensuring efficient data flow even when the network incurs an unexpected or real-time operational flareup or anomaly in signal transmissions or fluctuations.

In some examples, the global model 275 operates as a collaborative model receiving updates in real-time or periodically via an aggregator 270 that receives data transmissions 255 or model updates directly or via the model storage and aggregator 235. In some examples, the model storage 225 is composed of one or more servers 230 that implement the model storage. In some examples, the user equipment 210 (i.e., local devices) is configured to cause processing of the critical data to be handled locally whilst the other data deemed not critical or of less criticality is compressed at high, medium, or low compression ratios (compression module 265) for efficient transmission. For example, if the bandwidth is low, the neural network model 260 may receive parameter data of such and indicate an output for a lower compression ratio of a block of data for efficient transmission of the block of data.

In some examples, server 230 may operate as a hub for a collaborative effort. In some examples, the UEs with integral or robust signal connections contribute updates containing only the optimized block parameters to the global model 275 and also provide sufficient bandwidth for utilizing secure multi-party computation techniques to ensure data privacy. In other words, the controller may be configured to selectively determine whether updates are of sufficient merit (i.e., quality control) to warrant being submitted anonymously to the global model 275 to maintain a high level of accuracy to contributions being stored in the model storage 225 and distributed to the MEC servers 230 (model storage and aggregators 235). This iterative and continuous improvement process is also selective and enables an updated global model 275 to be generated that is constantly learning and adapting and available to meet immediate conditions that present themselves. Also, the updated model is shared back (distributed to) with all or available UEs, including those UEs that present themselves as struggling with signal reception issues. The result is that all UEs or most UEs with the MEC environment receive improvements in signal transmissions, each able to boost its performance and resilience. In some examples, the parameters used are directed to signal fluctuations or signal strength; however, any other suitable metric of signal qualities may be used.

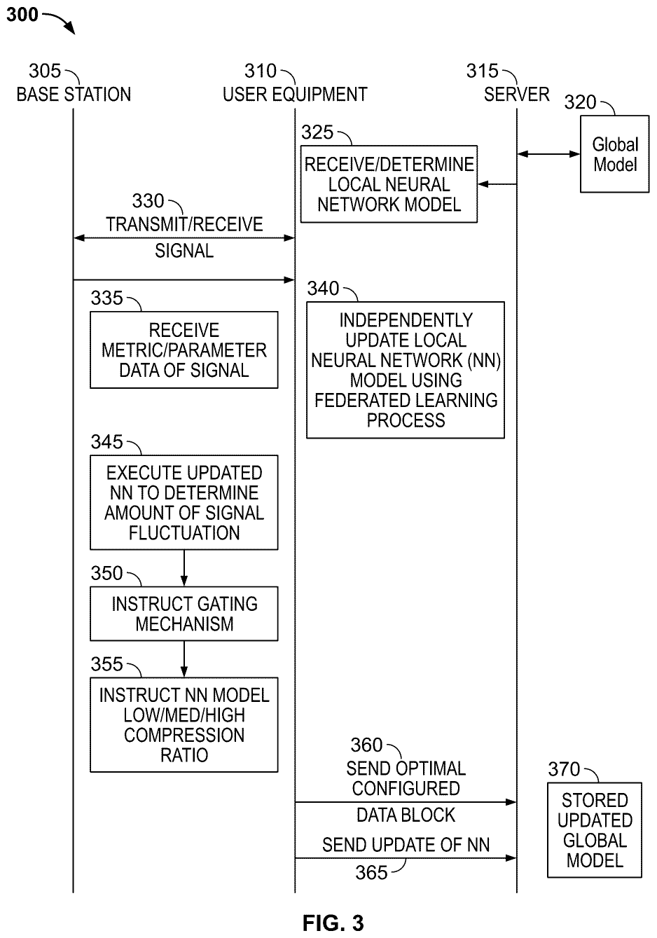

FIG. 3 illustrates an example diagram 300 of activities between the base station, the user equipment, and the server according to some embodiments. In FIG. 3, the example diagram 300 shows example communications corresponding to enabling evaluations of fluctuations in a received signal transmitted from a base station 305 to one or more user equipment 310 and applying a local neural network model to determine the amount of signal fluctuations based on metric data of one or more parameters being monitored about the received base station signal. Further, as illustrated in FIG. 3, the process of applying a local network model is derived or based in part on a global model stored at server 315.

At 330 in FIG. 3, a signal is transmitted from a base station 305 for receipt by one or more local equipment, 310, composed of local devices. In some examples, the user equipment may have been provisioned with a local neural network model at 325 or may receive a local neural network model stored at server 315. In some examples, the local neural network model may correspond to a global model stored at a server 315 or include features of the global model 257 configured for the local distribution. In some examples, the local neural network may be configured for slice-specific systems or one or more specific local devices of user equipment. In some examples, the local neural network may be configured based on feature sets or on locations of user equipment. In either case, the local neural network is applied to process transmission signals containing non-critical data that is not for on-device local processing. The local device may request specific parameters or metric data of the signal transmitted by the base station 305. At 340, once the metric data related to one or more transmitted parameters is received by the local user equipment (i.e., received by the local device), the metric data is inputted to a local neural network.

The local neural network implements a federated learning process of independently receiving input from the local user device. The output from the local neural network is used at 345 to determine the amount of signal fluctuation by the controller or processor locally configured with the user device. Once the signal fluctuation amount is determined, the local user device, via its processor or controller, instructs 350 operations of a gating mechanism 240 (of FIG. 2) that determines the optimal compression ratio for compressing a block of data before transmitting the data block to the server. At 355, an input is provided to the local neural network model of the metric data of a selected parameter related to the signal received. An output is generated from the local neural network of whether to apply a different compression ratio to a block of data to be transmitted by a local transceiver or transmitter located at the user device to an edge device within the MEC environment. The output of the local neural network determines an optimized compression ratio for compressing a block of data.

At 360, the data block with the optimized compression ratio for compressing data contained in the data block is transmitted to the edge device or other device at server 315. Also, at 365, one or more updates of the local neural network model are sent to server 315 to be shared with a global model at 370. By each user device making independent changes to its local neural network model, a federated learning process is enabled that protects the privacy of data access to each local device and modifications made by each local device to its localized neural network model.

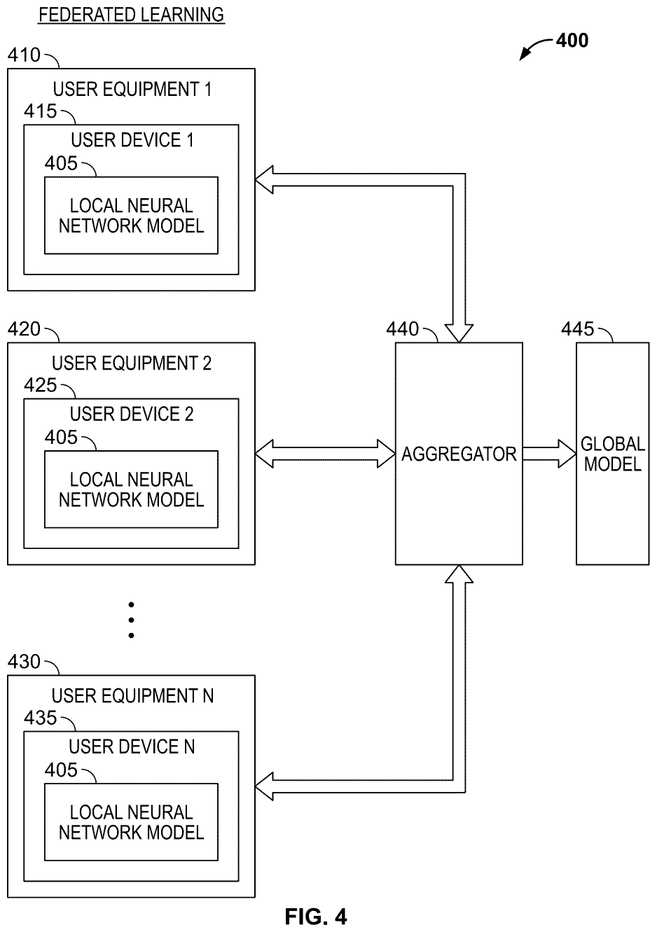

FIG. 4 is an exemplary federated learning process 400 of a collaborative, decentralized framework for sharing neural network model updates between the local user equipment and a global model remotely hosted according to some embodiments. The federated learning process 400 utilizes a federation of the distributed user equipment to learn; in this case, user equipment 410, user equipment 420, and user equipment 430 each perform model training of a local neural network (405) that is hosted on a respective user device (415, 420, 435). In some examples, after the training is completed for each user equipment (410, 420, 430), the updates to the local neural network (405) are transferred to an aggregator 440. The aggregator utilizes the local model data or metric parameter to update a global model 445, and the updates to the global model are eventually returned to the individual local learners of the respective user devices for their use. As a result, each local neural network (405) learns and benefits from the datasets of updates sent by the other learners only through the global model, shared by the aggregator 440, without explicitly accessing directly data stored on each user equipment, which could be privacy sensitive data.

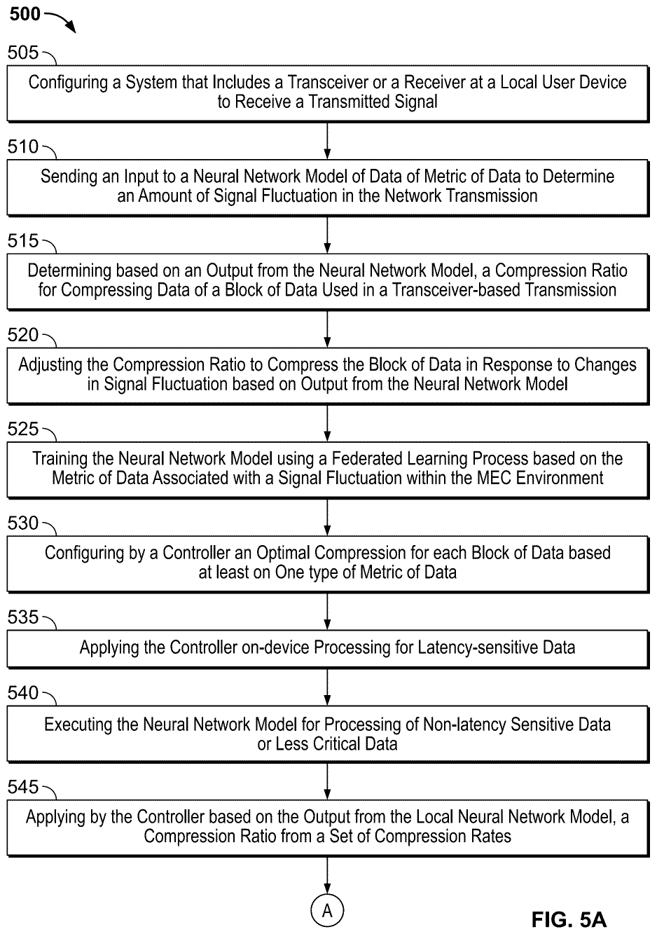

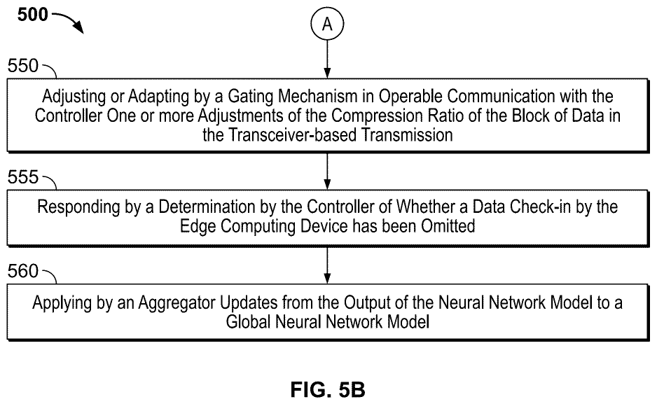

FIGS. 5A and 5B illustrate a flow diagram of an example method 500 for a system for Mobile edge computing that handles signal fluctuations and uses federated learning for distributed learning according to some embodiments. In some instances, a system may perform the techniques (e.g., one or more devices), such as a federated learning model and an adaptive gating mechanism to optimize data compression and transmission, on-device processing for latency-sensitive data, while using a local neural network model on the device for processing less urgent data. Systems and methods are configured to continuously monitor network metrics and choose the optimal compression block for each data packet before transmission.

In some embodiments, an aggregator is configured to selectively aggregate and send data to a global model; the global model is a centralized storage or repository for collecting and analyzing information from one or more distributed models. Method 500 illustrates one or more techniques that may be performed by a system that includes one processor or more than one processor. In instances, method 500 may be performed by one or more user equipment in a multi-access edge computing (MEC) environment where the user equipment is configured with a controller instructing a transceiver to receive downlink signals and uplink signals to and from a base station.

In FIGS. 5A and 5B, at 505, a system that includes a transceiver or a receiver controlled by a controller at a local user device of a user equipment is configured in an MEC environment to receive transmissions from an edge computing device. The transmissions may include data that may consist of one or more types of metric data about a signal that is being sent to the receiver from a base station within the MEC environment.

At 510, input is enabled by the controller of the system to a neural network model communicatively coupled to the controller. The input to the neural network model may include data of at least one type of metric of data that can be used to determine an amount of signal fluctuation in the network transmission. Once the metric data related to one or more transmitted parameters is received by the local user equipment (i.e., received by the local device), the metric data is inputted to a local neural network. The neural network model applies a federated learning process model to determine whether or not to change the compression ratio of data blocks to be sent to an edge device because of fluctuations in a transmitted signal. The local neural network may be configured for slice-specific systems or one or more specific local devices of user equipment. In some examples, the local neural network may be configured based on feature sets or on locations of user equipment. In either case, the local neural network is applied to process transmission signals containing non-critical data that is not for on-device local processing.

At 515, the controller on the local user device determines, based on an output from the neural network model, a compression ratio for compressing data of a block of data used in a transceiver-based transmission to an edge computing device within the MEC environment.

At 520, the compression ratio is iteratively adjusted by the controller to compress the block of data in response to changes in signal fluctuation based on output from the neural network model to enhance the transceiver-based transmission to the edge computing device within the MEC environment. Once the signal fluctuation amount is determined, the local user device, via its processor or controller, instructs operations of an adaptive gating mechanism to configure the optimal compression ratio for compressing a block of data before transmitting the data block to the server or an edge device. The input that was provided to the local neural network model of the metric data of a selected parameter related to the signal received determined the output and how to control the compression ratio for an optimal output.

At 525, the training of the neural network model is performed. The training process uses a federated learning process based on at least one type of metric of data associated with a signal fluctuation that is received by the local device within the MEC environment. The federated learning network utilizes a federation of distributed user equipment to learn. This entails that the user equipment(s) each perform independent model training of a local neural network that is hosted on a respective user device.

At 530, the configuring process by a controller of an optimal compression for each block of data based at least on one type of metric of data of a plurality of metrics of data is performed. This operation is performed before transmitting the block of data to the edge computing device within the MEC environment. The configuring operations of the controller may be performed in real-time, periodically, or when an event, such as a signal fluctuation above a certain threshold, would necessitate a change in the compression ratio of the data blocks to be transmitted that has a material or at least some effect on the transmission optimization.

At 535, the controller-based on-device processing for latency-sensitive data is applied. That is, the controller decides whether or not to execute the neural network model. For particular types of data deemed critical or latency-sensitive, the neural network model is bypassed, and the processing is performed on the device. The system combines on-device processing for latency-sensitive data with a dynamically adaptive federated neural network compression (FDNNC) model for less critical data, ensuring enhanced uninterrupted responsiveness and efficient off-loading during different kinds or amounts of signal fluctuations. In some examples, the on-device processing may be considered a localized function that enables instant or nearly instantaneous decision-making without requiring input from a remote resource or third-party authority to formulate a decision (i.e., without needing to consult a distant authority.

At 540, the process of executing by a controller, the neural network model for the processing of non-latency sensitive data or less critical data is performed. In some examples, the FDNNC Model and the Adaptive Gating Mechanism contain the network metrics and the optimal block configuration means to determine high, medium, and low compression ratios. Hence, a more flexible approach can be used for less urgent data. This is where the FDNNC model, residing on the device, functions. It boasts multiple neural network compression blocks, each offering different levels of compression (high, medium, low). A smart or adaptive gating mechanism continuously monitors network metrics 245, like signal strength and bandwidth.

At 545, a process of applying by the controller based on the output from the local neural network model, a particular compression is applied. The compression ratio is one selected from a set of compression rates of a high compression ratio, a medium compression ratio, or a low compression ratio.

At 550, the process of adjusting or adapting by an adaptive gating mechanism in operable communication with the controller requires one or more adjustments of the compression ratio of the block of data in the transceiver-based transmission. The FDNNC model is the basis for the adaptive gating mechanism, categorizing compressions into high, medium, and low.

At 555, a process of responding by a determination by the controller of whether a data check-in by the edge computing device has been omitted is performed. If an omission is determined, then the controller applies a process using a previously received update from the controller to compensate for an omitted data check-in to adjust the compression ratio of the block of data in the transceiver-based transmission.

At 560, a process of applying by aggregator updates from the output of the neural network model to a global neural network model hosted within the MEC environment is performed. The aggregator utilizes the local model data or metric parameter to update a global model, and the updates to the global model are eventually returned to the individual local learners of the respective user devices for their use. As a result, each local neural network learns and benefits from the datasets of updates sent by the other learners only through the global model, shared by the aggregator, without explicitly accessing directly data stored on each user equipment, which could be privacy-sensitive data.

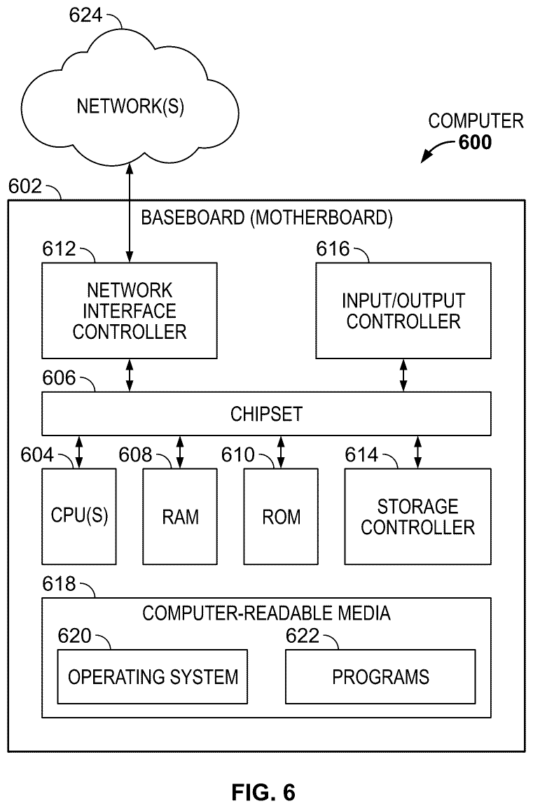

FIG. 6 shows an example of computer architecture for a device capable of executing program components for implementing the functionality described above. The computer architecture shown in FIG. 6 illustrates any type of computer 600, such as a conventional server computer, workstation, desktop computer, laptop, tablet, network appliance, e-reader, smartphone, or other computing device, and can be utilized to execute any of the software components presented herein.

The computer 600 includes a baseboard 602, or “motherboard,” which is a printed circuit board to which a multitude of components or devices can be connected by way of a system bus or other electrical communication paths. In one illustrative configuration, one or more central processing units (“CPUs”) 604 operate in conjunction with a chipset 606. The CPU 604 can be a standard programmable processor that performs the arithmetic and logical operations necessary for the operation of the Computer 600.

The CPUs 604 perform operations by transitioning from one discrete physical state to the next by manipulating switching elements that differentiate between and change these states. Switching elements generally include electronic circuits that maintain one of two binary states, such as flip-flops, and electronic circuits that provide an output state based on the logical combination of the states of one or more other switching elements, such as logic gates. These essential switching elements can be combined to create more complex logic circuits, including registers, adders-subtractors, arithmetic logic units, floating-point units, etc.

The chipset 606 provides an interface between the CPU 604 and the remainder of the components and devices on the baseboard 602. The chipset 606 can provide an interface to a RAM 608, which is used as the main memory in computer 600. The chipset 606 can further provide an interface to a computer-readable storage medium such as a read-only memory (“ROM”) 610 or non-volatile RAM (“NVRAM”) for storing basic routines that help to startup the computer 600 and to transfer information between the various components and devices. The ROM 610 or NVRAM can also store other software components necessary for the operation of the computer 600 in accordance with the configurations described herein.

The computer 600 can operate in a networked environment using logical connections to remote computing devices and computer systems through a network, such as network(s) 106. The chipset 606 can include functionality for providing network connectivity through a NIC 612, such as a gigabit Ethernet adapter. The NIC 612 is capable of connecting the computer 600 to other computing devices over the network(s) 106. It should be appreciated that multiple NICs 612 can be present in the computer 600, connecting the computer to other types of networks and remote computer systems.

The computer 600 can be connected to a storage device 618 that provides non-volatile storage for the computer. The storage device 618 can store an operating system 620, programs 622, and data, which have been described in greater detail herein. The storage device 618 can be connected to the computer 600 through a storage controller 614 connected to the chipset 606. The storage device 618 can consist of one or more physical storage units. The storage controller 614 can interface with the physical storage units through a serial attached SCSI (“SAS”) interface, a serial advanced technology attachment (“SATA”) interface, a fiber channel (“FC”) interface, or other type of interface for physically connecting and transferring data between computers and physical storage units.

The computer 600 can store data on the storage device 618 by transforming the physical state of the physical storage units to reflect the information being stored. The specific transformation of the physical state can depend on various factors in different embodiments of this description. Examples of such factors can include but are not limited to, the technology used to implement the physical storage units, whether the storage device 618 is characterized as primary or secondary storage, and the like.

For example, the computer 600 can store information to the storage device 618 by issuing instructions through the storage controller 614 to alter the magnetic characteristics of a particular location within a magnetic disk drive unit, the reflective or refractive characteristics of a particular location in an optical storage unit, or the electrical characteristics of a particular capacitor, transistor, or other discrete components in a solid-state storage unit. Other transformations of physical media are possible without departing from the scope and spirit of the present description, with the foregoing examples provided only to facilitate this description. The computer 600 can further read information from storage device 618 by detecting the physical states or characteristics of one or more particular locations within the physical storage units.

In addition to the mass storage device 618 described above, the computer 600 can have access to other computer-readable storage media to store and retrieve information, such as program modules, data structures, or other data. It should be appreciated by those skilled in the art that computer-readable storage media is any available media that provides for the non-transitory storage of data and that can be accessed by the computer 600. In some examples, the operations performed by a controller of a local user device or user equipment and/or any components included therein may be supported by one or more devices similar to computer 600. As stated otherwise, some or all of the operations performed by controller and user devices and or any components included therein may be performed by one or more computers.

By way of example, and without limitation, computer-readable storage media can include volatile and non-volatile, removable and non-removable media implemented in any method or technology. Computer-readable storage media includes but is not limited to RAM, ROM, erasable programmable ROM (“EPROM”), electrically-erasable programmable ROM (“EEPROM”), flash memory, or other solid-state memory technology, compact disc ROM (“CD-ROM”), digital versatile disk (“DVD”), high definition DVD (“HD-DVD”), BLU-RAY, or other optical storage, magnetic cassettes, magnetic tape, magnetic disk storage or other magnetic storage devices, or any other medium that can be used to store the desired information in a non-transitory fashion.

As mentioned briefly above, the storage device 618 can store an operating system 620 utilized to control the operation of the computer 600. According to one embodiment, the operating system comprises the LINUX operating system. According to another embodiment, the operating system comprises the WINDOWS® SERVER operating system from MICROSOFT Corporation of Redmond, Washington. According to further embodiments, the operating system can comprise the UNIX operating system or one of its variants. It should be appreciated that other operating systems can also be utilized. The storage device 618 can store other system or application programs and data utilized by the computer 600.

In one embodiment, the storage device 618 or other computer-readable storage media is encoded with computer-executable instructions which, when loaded into the computer 600, transform the computer from a general-purpose computing system into a special-purpose computer capable of implementing the embodiments described herein. These computer-executable instructions transform the computer 600 by specifying how the CPU 604 transitions between states, as described above. According to one embodiment, the computer 600 has access to computer-readable storage media storing computer-executable instructions which, when executed by the computer 600, perform the various processes described above with regard to FIGS. 1-5. The computer 600 can also include computer-readable storage media with instructions stored thereupon for performing any of the other computer-implemented operations described herein.

The computer 600 can also include one or more input/output controllers 616 for receiving and processing input from a number of input devices, such as a keyboard, a mouse, a touchpad, a touch screen, an electronic stylus, or other type of input device. Similarly, an input/output controller 616 can provide output to a display, such as a computer monitor, a flat-panel display, a digital projector, a printer, or other type of output device. It will be appreciated that the computer 600 might not include all of the components shown in FIG. 6, it can include other components that are not explicitly shown in FIG. 6, or it might utilize an architecture completely different than that shown in FIG. 6.

As described herein, the computer 600 may comprise one or more controllers and/or any other devices. The computer 600 may include one or more hardware processors (e.g., such as CPUs 604 (processors)) configured to execute one or more stored instructions. The processor(s) may comprise one or more cores. Programs 622 may comprise any type of program or process to perform the techniques described in this disclosure for utilizing a transport controller to provide a critical mapping from intent to actual transport network characteristics when selecting and placing network slices.

Additionally, or alternatively, program 622 may cause the computer 600 to perform techniques, including causing the controller to input and output data related to metrics of a transmission signal to a neural network model and to adjust the compression ratio of blocks of data to be transmitted from a transceiver or like device hosted locally for sending to a remote edge device or server.

Clause 1. A user equipment for processing data in a multi-access edge computing (MEC) environment, comprising: a transceiver; and a controller coupled to the transceiver configured to: receive, from an edge computing device, data that comprises at least one type of metric of data related to a network transmission received by the transceiver within the MEC environment; input, to a neural network model communicatively coupled to the controller, data of the at least one type of metric of data to determine an amount of signal fluctuation in the network transmission; determine, based on an output from the neural network model, a compression ratio for compressing data of a block of data used in a transceiver-based transmission to an edge computing device within the MEC environment; and iteratively adjust the compression ratio for compressing the block of data in response to changes in the amount of signal fluctuation based on output from the neural network model to enhance the transceiver-based transmission to the edge computing device within the MEC environment.

Clause 2. The user equipment of clause 1, wherein the neural network model is trained using a federated learning process based on at least one type of metric of data associated with a signal fluctuation within the MEC environment.

Clause 3. The user equipment of clause 1, wherein the controller is further configured to select an optimal compression for each block of data based at least on one type of metric of data of a plurality of metrics of data before transmitting the block of data to the edge computing device within the MEC environment.

Clause 4. The user equipment of clause 1, wherein the controller is further configured to apply on-device processing for latency sensitive data.

Clause 5. The user equipment of clause 1, wherein the controller is further configured to execute the neural network model for processing of non-latency sensitive data or less critical data.

Clause 6. The user equipment of clause 1, wherein the controller is further configured to apply a plurality of compression rates comprising at least one of a high compression ratio, a medium compression ratio, or a low compression ratio based on the output from the neural network model.

Clause 7. The user equipment of clause 1, further comprising a gating mechanism in operable communication with the controller wherein the gating mechanism is configured as an adaptive gating mechanism to enable adjusting the compression ratio of the block of data in the transceiver-based transmission.

Clause 8. The user equipment of clause 7, wherein the adaptive gating mechanism is further configured to respond to a determination by the controller of whether a data check-in by the edge computing device has been omitted and to use a previously received update from the controller to compensate for an omitted data check-in to adjust the compression ratio of the block of data in the transceiver-based transmission.

Clause 9. The user equipment of clause 1 wherein the network transmission further comprises an uplink transmission received from the transceiver and a downlink transmission sent to the transceiver from the edge computing device within the MEC environment.

Clause 10. The user equipment of clause 1 wherein the controller is configured to send data generated by an update from the output of the neural network model to a global neural network model hosted within the MEC environment.

Clause 11. A method for processing data comprising: receiving, by a local device in a Multi-access Edge Computing (MEC) environment, a transmission of a radio frequency signal from an edge device within the MEC environment; determining, by the local device, at least one metric of data related to the transmission of the radio frequency signal from the edge device within the MEC environment; inputting, by the local device in operable communication with a neural network model, the at least one metric of data to the neural network model wherein the neural network model is trained using a federated learning process based on metric data associated with at least one radio frequency signal transmission; receiving, by the local device, an output from the neural network model that provides an evaluation of signal fluctuation in the transmission of the radio frequency signal to the local device based on inputted metric data; and iteratively changing, by the local device based on the output from the neural network model, a compression ratio to apply for compressing a data block in the transmission of a radio signal from the local device to the edge device in an MEC environment wherein the data block is being compressed in accordance with signal fluctuation from the transmission from the edge device.

Clause 12. The method of clause 11, further comprising processing on-device, by the local device, for latency sensitive data or critical data in transmissions between the local device and edge device.

Clause 13. The method of clause 11, further comprising using, by the local device, the neural network model for processing of non-latency sensitive data or less critical data in transmission between the local device and the edge device.

Clause 14. The method of clause 11, further comprising selecting, by the local device, an optimal compression block for each data block before transmission to the edge device.

Clause 15. The method of clause 11, further comprising training a neural network model hosted at a local device via the federated learning process using an independent input of metric data from at least one local device.

Clause 16. The method of clause 11, further comprising enabling, by the local device, an adaptive gating mechanism for adjusting the compression ratio of the data block in the transmission of data between the local device and the edge device.

Clause 17. The method of clause 16, wherein the compression ratio comprises at least one of a high compression ratio, a medium compression ratio, or a low compression ratio.

Clause 18. The method of clause 11, further comprising sending, by the local device, one or more updates of changes to the neural network model to a global network model remotely hosted by a server in the MEC environment.

Clause 19. A system comprising: one or more processors; and non-transitory computer-readable media storing instructions that, when executed by the one or more processors, cause the system to perform operations comprising: receiving, by a local device in a Multi-access Edge Computing (MEC) environment, a transmission of a radio frequency signal from an edge device within the MEC environment; determining, by the local device, at least one type of metric of data related to the transmission of the radio frequency signal from the edge device within the MEC environment; inputting, by the local device in operable communication with a neural network model, the at least one type of metric of data to the neural network model wherein the neural network model is trained using a federated training process based on at least one type of metric of data associated with at least one radio frequency signal transmission; receiving, by the local device, an output from the neural network model that provides an evaluation of signal fluctuation in the transmission of the radio frequency signal to the local device based on inputted metric data; and iteratively changing, by the local device based on the output from the neural network model, a compression ratio to apply for compressing a data block in the transmission of a radio signal from the local device to the edge device in an MEC environment wherein the data block is being compressed in accordance with signal fluctuation from the transmission from the edge device.

Clause 20. The system of clause 19, further comprising a gating mechanism in operable communication with the local device wherein the gating mechanism is configured as an adaptive gating mechanism to enable adjusting the compression ratio of block data in a transmission between the local device and the edge device.

Aspects of the present disclosure are described herein with reference to flowchart illustrations and/or block diagrams of methods, apparatuses (systems), and computer program products according to embodiments presented in this disclosure. It will be understood that each block of the flowchart illustrations and/or block diagrams, and combinations of blocks in the flowchart illustrations and/or block diagrams, can be implemented by computer program instructions. These computer program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the block(s) of the flowchart illustrations and/or block diagrams.

In this way, the techniques described herein enable While the invention is described with respect to the specific examples, it is to be understood that the scope of the invention is not limited to these specific examples. Since other modifications and changes varied to fit particular operating requirements and environments will be apparent to those skilled in the art, the invention is not considered limited to the example chosen for purposes of disclosure, and covers all changes and modifications which do not constitute departures from the true spirit and scope of this invention.

Although the application describes embodiments having specific structural features and/or methodological acts, it is to be understood that the claims are not necessarily limited to the specific features or acts described. Rather, the specific features and acts are merely illustrative some embodiments that fall within the scope of the claims of the application.

What is claimed is:

1. A user equipment for processing data in a multi-access edge computing (MEC) environment, comprising:
a transceiver; and
a controller coupled to the transceiver configured to:
receive, from an edge computing device, data that comprises at least one type of metric of data related to a network transmission received by the transceiver within the MEC environment;
input, to a neural network model communicatively coupled to the controller, data of the at least one type of metric of data to determine an amount of signal fluctuation in the network transmission;
determine, based on an output from the neural network model, a compression ratio for compressing data of a block of data used in a transceiver-based transmission to an edge computing device within the MEC environment; and
iteratively adjust the compression ratio for compressing the block of data in response to changes in the amount of signal fluctuation based on output from the neural network model to enhance the transceiver-based transmission to the edge computing device within the MEC environment.

2. The user equipment of claim 1, wherein the neural network model is trained using a federated learning process based on at least one type of metric of data associated with a signal fluctuation within the MEC environment.

3. The user equipment of claim 1, wherein the controller is further configured to select an optimal compression for each block of data based at least on one type of metric of data of a plurality of metrics of data before transmitting the block of data to the edge computing device within the MEC environment.

4. The user equipment of claim 1, wherein the controller is further configured to apply on-device processing for latency sensitive data.

5. The user equipment of claim 1, wherein the controller is further configured to execute the neural network model for processing of non-latency sensitive data or less critical data.

6. The user equipment of claim 1, wherein the controller is further configured to apply a plurality of compression rates comprising at least one of a high compression ratio, a medium compression ratio, or a low compression ratio based on the output from the neural network model.

7. The user equipment of claim 1, further comprising a gating mechanism in operable communication with the controller wherein the gating mechanism is configured as an adaptive gating mechanism to enable adjusting the compression ratio of the block of data in the transceiver-based transmission.

8. The user equipment of claim 7, wherein the adaptive gating mechanism is further configured to respond to a determination by the controller of whether a data check-in by the edge computing device has been omitted and to use a previously received update from the controller to compensate for an omitted data check-in to adjust the compression ratio of the block of data in the transceiver-based transmission.

9. The user equipment of claim 1 wherein the network transmission further comprises an uplink transmission received from the transceiver and a downlink transmission sent to the transceiver from the edge computing device within the MEC environment.

10. The user equipment of claim 1 wherein the controller is configured to send data generated by an update from the output of the neural network model to a global neural network model hosted within the MEC environment.

11. A method for processing data comprising:
receiving, by a local device in a Multi-access Edge Computing (MEC) environment, a transmission of a radio frequency signal from an edge device within the MEC environment;
determining, by the local device, at least one metric of data related to the transmission of the radio frequency signal from the edge device within the MEC environment;
inputting, by the local device in operable communication with a neural network model, the at least one metric of data to the neural network model wherein the neural network model is trained using a federated learning process based on metric data associated with at least one radio frequency signal transmission;
receiving, by the local device, an output from the neural network model that provides an evaluation of signal fluctuation in the transmission of the radio frequency signal to the local device based on inputted metric data; and
iteratively changing, by the local device based on the output from the neural network model, a compression ratio to apply for compressing a data block in the transmission of a radio signal from the local device to the edge device in an MEC environment wherein the data block is being compressed in accordance with signal fluctuation from the transmission from the edge device.

12. The method of claim 11, further comprising processing on-device, by the local device, for latency sensitive data or critical data in transmissions between the local device and edge device.

13. The method of claim 11, further comprising using, by the local device, the neural network model for processing of non-latency sensitive data or less critical data in transmission between the local device and the edge device.

14. The method of claim 11, further comprising selecting, by the local device, an optimal compression block for each data block before transmission to the edge device.

15. The method of claim 11, further comprising training a neural network model hosted at a local device via the federated learning process using an independent input of metric data from at least one local device.

16. The method of claim 11, further comprising enabling, by the local device, an adaptive gating mechanism for adjusting the compression ratio of the data block in the transmission of data between the local device and the edge device.

17. The method of claim 16, wherein the compression ratio comprises at least one of a high compression ratio, a medium compression ratio, or a low compression ratio.

18. The method of claim 11, further comprising sending, by the local device, one or more updates of changes to the neural network model to a global network model remotely hosted by a server in the MEC environment.

19. A system comprising:
one or more processors; and
non-transitory computer-readable media storing instructions that, when executed by the one or more processors, cause the system to perform operations comprising:
receiving, by a local device in a Multi-access Edge Computing (MEC) environment, a transmission of a radio frequency signal from an edge device within the MEC environment;
determining, by the local device, at least one type of metric of data related to the transmission of the radio frequency signal from the edge device within the MEC environment;
inputting, by the local device in operable communication with a neural network model, the at least one type of metric of data to the neural network model wherein the neural network model is trained using a federated training process based on at least one type of metric of data associated with at least one radio frequency signal transmission;
receiving, by the local device, an output from the neural network model that provides an evaluation of signal fluctuation in the transmission of the radio frequency signal to the local device based on inputted metric data; and
iteratively changing, by the local device based on the output from the neural network model, a compression ratio to apply for compressing a data block in the transmission of a radio signal from the local device to the edge device in an MEC environment wherein the data block is being compressed in accordance with signal fluctuation from the transmission from the edge device.

20. The system of claim 19, further comprising a gating mechanism in operable communication with the local device wherein the gating mechanism is configured as an adaptive gating mechanism to enable adjusting the compression ratio of block data in a transmission between the local device and the edge device.
